(19) United States
(12) Patent Application Publication
(10) Pub. No.: US 2013/0100752 A1
(43) Pub. Date: Apr. 25, 2013

(54) METHOD OF RESTORING RECONSTRUCTED MEMORY SPACES

(71) Applicant: Yung-Chiang Chu, Taipei (TW)

(72) Inventor: Yung-Chiang Chu, Taipei (TW)

(73) Assignee: FLUIDITECH IP LIMITED, Victoria (SC)

(21) Appl. No.: 13/278,006

(22) Filed: Oct. 20, 2011

(51) Int. Cl. G11C 29/00

(52) U.S. Cl. 365/201

(57) ABSTRACT

A method of restoring reconstructed memory spaces is applied for restoring usable memory spaces in an inked die to form the memory with a standardized or non-standardized memory capacity. The method comprises the steps of scanning at least one selected from a block, a page and a cell in a die (or a memory unit), and writing/reading/comparing testing data in each selected area for labeling the block, page and cell as normal and abnormal in each area. The aforementioned steps are executed in a loop to achieve the effects of scanning and testing the die completely, using the configured and collected area labeled as normal to reconstruct the memory with the standardized or non-standardized memory capacity, and providing the memory to any controller or server to access the memory capacity.

### FIELD OF THE INVENTION

The present invention relates to a method of restoring reconstructed memory spaces, in particular to the method of restoring usable memory spaces from an inked die and reconstructing a memory with a standardized or non-standardized memory capacity.

### BACKGROUND OF THE INVENTION

As network enters into a new era of cloud applications, data of commercial applications of an individual company are generally introduced to a cloud server, and optical fibers, WI-FI and mobile communications become popular, so that the consumption of flash memories grows rapidly. In addition, the cloud server generally adopts a high-end SSD to improve performance, and the high demand of such applications also accelerates the growth of the capacity of the SSD, and the quantity of flash memories used in these consumer electronic devices increases drastically, particularly with the blooming of Smartphones and flat panel PCs.

In the manufacturing process of the flash memory, dies are formed on a wafer and diced for the aforementioned applications. However, the yield rate cannot reach 100% due to the manufacturing process. For example, the dies of a wafer as shown in FIG. 1 is tested, and there are approximately 656 usable dices and 106 defective dies in the testing dies, and thus the yield rate is approximately equal to 85% only. In other words, the defective rate is up to 15%, and the defective dies will be eliminated and discarded. In fact, not all of the defective dies are useless. With reference to FIG. 2 for good dies and FIG. 3 for defective dies (indicated by black dots), many cells as shown in FIG. 3 are not damaged, and some portions of each cell are considered non-defects, and these portions still can be used. Discarding such dies is a waste of resources.

Therefore, it is a main subject for the present invention to provide a method to overcome the foregoing problem.

### SUMMARY OF THE INVENTION

It is a primary objective of the present invention to provide a method of restoring reconstructed memory spaces, so that usable memory spaces can be restored from an inked die to form a memory with a standardized or non-standardized memory capacity.

To achieve the foregoing objective, the present invention reads/writes/compares blocks, pages, and/or cells in a die by the aforementioned method to obtain the density distribution of the normal and abnormal blocks, pages and cells for a new allocation in order to reconstruct the memory.

Another objective of the present invention is to provide an end of product to determine whether at least one of the blocks, pages and cells is normal according to the aforementioned method, so as to configure, collect and label at least one of the normal blocks, pages and cells to achieve the effect of dynamically forming the memory with a standardized or non-standardized memory capacity.

To achieve the aforementioned objectives and other objectives, the present invention provides a method of restoring reconstructed memory spaces, and the method is applied for restoring usable memory spaces in an inked die to form a memory with a standardized or non-standardized memory capacity. The method comprises the steps of: (a) providing a die having a block, a page and a cell; (b) scanning at least one of the blocks, pages and cells of the die, and writing testing data into each area corresponding to the die, so that the die can produce a testing result by writing, reading and comparing the testing data, and the testing result is used for labeling normal and abnormal blocks, pages or cells; (c) writing the testing result into a spare area, and displaying a density distribution of at least one of normal and abnormal blocks, pages and cells in the die; (d) determining whether at least one of all blocks, pages and cells of the die has been scanned and tested to repeat the aforementioned steps selectively; and (f) configuring and collectively labeling at least one of the normal blocks, pages and cells to reconstruct the memory with the standardized or non-standardized memory capacity.

Compared with the prior art, the method of restoring reconstructed memory spaces of the present invention is applied for restoring a plurality of defective dies in a wafer, such that the die can be scanned and tested by any mode of the block, page and cell to search for a normal area (which can be used for reading/writing/comparing data), and the testing result is produced after the scanning and testing procedures, and the blocks, pages and cells are totally re-configured according to an algorithm, wherein each normal area is reused, and each abnormal area is deleted to prevent misuses.

In addition, not all of the re-configured areas have a standardized memory capacity equal to a power of two (such as the capacity of 2 GB, 4 GB, 8 GB or 256 GB), but they can have any memory capacity (such as the capacity of 3.5 GB, 800 MB or 460 GB). In other words, the present invention maximizes the restoration of a memory unit of each normal area, obtains memories, particularly those with a non-standardized memory capacity through the reconfiguration, and allows servers or control units to execute an operation of reading/writing/comparing/deleting data in the same way as the traditional memory.

### BRIEF DESCRIPTION OF THE DRAWINGS

FIG. 1 is a conventional testing program used for testing a plurality of dies on a wafer;

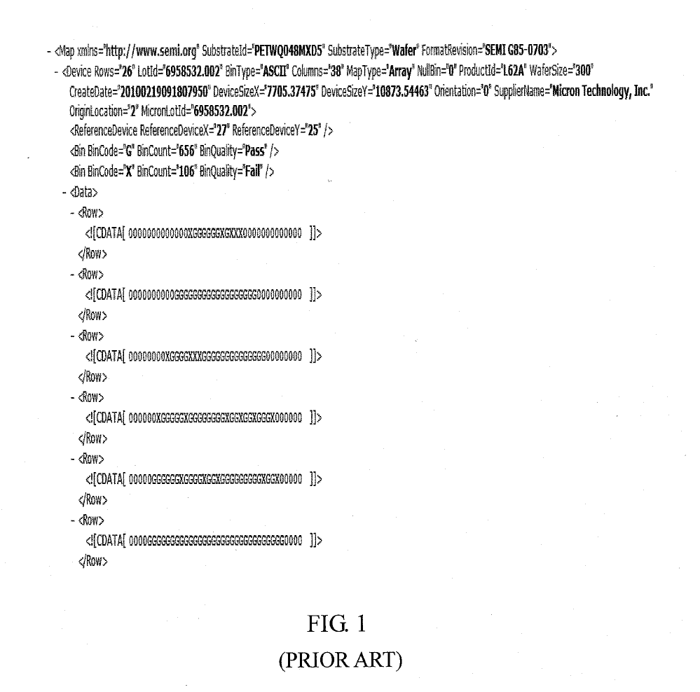

FIG. 2 is a schematic block diagram of a good die as depicted in FIG. 1;

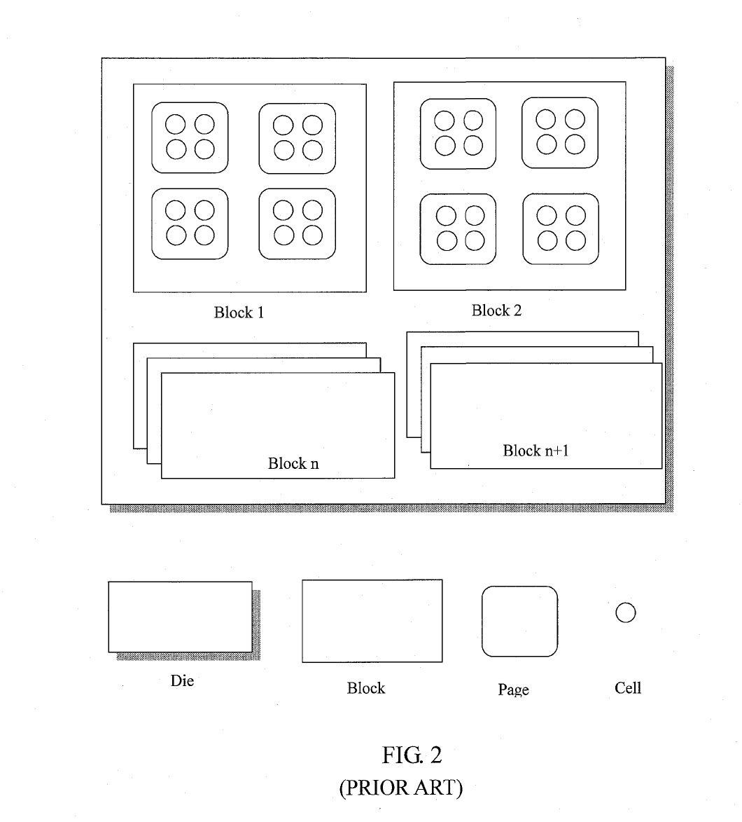

FIG. 3 is a schematic block diagram of a defective die as depicted in FIG. 1; and

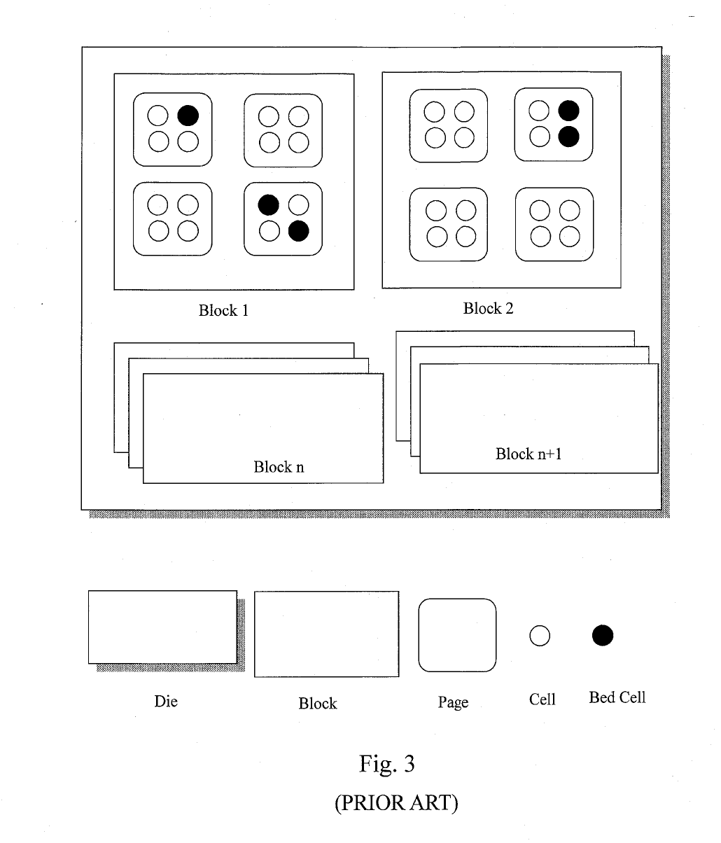

FIG. 4 is a flow chart of a method of restoring reconstructed memory spaces in accordance with a preferred embodiment of the present invention.

### DETAILED DESCRIPTION OF THE PREFERRED EMBODIMENTS

The objects, characteristics and effects of the present invention will become apparent with the detailed description of the preferred embodiments and the illustration of related drawings as follows.

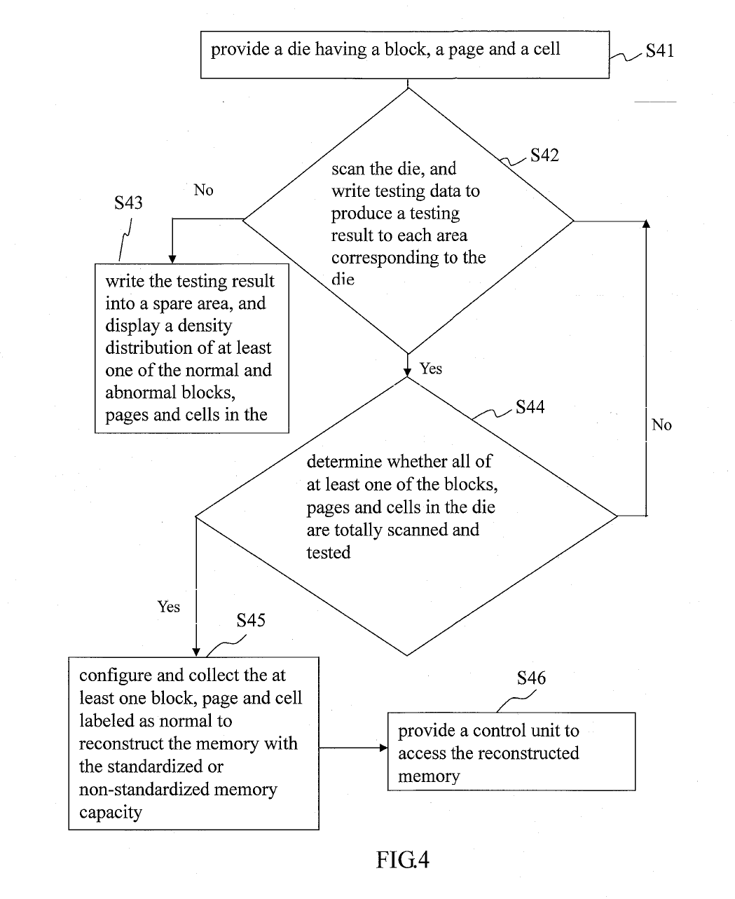

With reference to FIG. 4 for a flow chart of a method of restoring reconstructed memory spaces in accordance with a preferred embodiment of the present invention, the method is applied for restoring usable memory space in an inked die to form a memory with a standardized or non-standardized memory capacity. Wherein, the inked die includes (a) a memory die which is not founded as a defective die, but the die has a partial function only and includes some usable cells; (b) a memory die fails to have any response due to an open circuit or a short circuit; (c) a normal memory die including a general defect and a part or the whole of usable memory cells; and (d) a memory die misjudged as a defect in a functional testing process. Wherein, the memory is an NOR flash memory, an NAND flash memory or a dynamic random access memory (DRAM).

In addition, the standardized memory capacity is defined as a conventional memory capacity equal to a power of two, such as the capacity of 2 GB, 4 GB, 8 GB, 16 GB, 32 GB or 64 GB; and the non-standardized memory capacity is defined as a memory capacity not equal to a power of two, such as the capacity of 3.5 GB, 800 MB or 460 GB.

The method of restoring reconstructed memory spaces comprises the following steps.

Step S41: Provide a die having a block, a page and a cell. In general, the dies are formed in different forms on a wafer, wherein the die can be divided into a block, a page and a cell according to a planned memory area, and the cell is the least storage unit of each die provided for storing data in bits 0 and 1. In addition, the page is a set of a plurality of cells, and the set of the page can become the block, and finally the blocks can form the die which is also known as a memory unit.

Step S42: Write at least one of the blocks, pages and cells of the die, and write testing data into each area corresponding to the die, so that the die can produce a testing result by executing an operation of writing, reading, and comparing the testing data. The testing result is used for labeling the normal and abnormal block, page or cell. In this step, the block, page or cell of the die can be scanned selectively. In other words, the cell of the least storage bit or even the block with scanned and stored character data can be scanned. In addition, the testing data can be written/read/compared in each selected area and provided for testing whether each area is normal. In other words, the area is provided for performing the operation of writing/reading/comparing normal data, and the test as described in this step can obtain a distribution of the normal and abnormal block, page or cell in the die. With such labeling method, the distribution of the normal and abnormal conditions can be labeled.

In addition, the at least one of the blocks, pages and cells labeled as abnormal shows that the blocks, the pages and the cells are bad blocks, bad pages and bad cells respectively, and cannot execute an operation of writing, reading and comparing the testing data.

After the testing data are written into each area corresponding to the die, the method determines whether the testing data are written into each area, and the written testing data are read from each area and provided for comparing a difference between previous and present testing data to determine whether each area is normal or abnormal.

Step S43: Write the testing result into a spare area and display a density distribution of at least one of the normal and abnormal blocks, pages and cells in the die. In this step, the distribution of the blocks, pages and cells labeled as normal and abnormal is recorded into the spare area. In other words, the content recorded in the spare area allows us to know about the distribution of the normal and abnormal areas in the die.

Step S44: Determine whether all of the at least one of the blocks, pages and cells in the die are scanned and tested completely to repeat the aforementioned steps selectively. In this step, a loop is provided to determine whether to execute the foregoing steps S41˜S43, such that all of the selected blocks, pages or cells in the die can be scanned completely.

Step S45: Configure and collect the at least one of the blocks, pages and cells labeled as normal to reconstruct the memory with a standardized or non-standardized the memory capacity. In other words, all of the blocks, pages or cells in the die can be scanned and tested according to the aforementioned step to confirm all usable blocks, pages and cells capable of accessing data. With the reconfiguration, users can use the normal blocks, pages and cells for accessing data. In addition, the memory capacity formed by the block, the page or the cell can be a standardized memory capacity or a non-standardized memory capacity. By the aforementioned steps, usable blocks, pages or cells can be restored to form the memory with the memory capacity.

In addition, the step of configuring the dies labeled as normal further comprises the steps of selecting the at least one of the normal blocks, pages and cells from the spare area, deleting the at least one of the abnormal blocks, pages and cells, and reconfiguring and reconstructing the memory based on the at least one of the selected normal blocks, pages and cells.

In another preferred embodiment, the at least one of the configured and collected blocks, pages and cells labeled as normal is tested by an error correction code engine (ECC Engine) for dynamically determining whether at least one of the blocks, pages and cells is normal, and configure and collect at least one of the blocks, pages and cells labeled as normal again for dynamically forming the memory with the standardized or non-standardized memory capacity. For example, the memory having an original memory capacity of 90 GB is reconfigured and the damaged area is deleted to reduce the memory capacity of the memory to 64 GB.

In addition, the present invention provides users a restored memory with a standardized or non-standardized memory capacity, and the method of the invention further comprises Step S46 that provides a control unit to access the reconstructed memory, wherein the memory capacity of the memory is formed by reconfiguring the normal block.

The method of restoring reconstructed memory spaces in accordance with the present invention can be used for restoring a plurality of defective dies in a wafer, so that the dies can be scanned and tested by any one of the block, page and cell to search for a normal area (showing that the operation of reading/writing/comparing data can be performed), and the testing result is produced after the scanning and testing procedures are completed, and the blocks, pages and cells can be reconfigured completely by an algorithm, wherein each normal area can be reused, and each abnormal area is deleted to prevent misuses.

In addition, not all of the reconfigured areas have a standardized memory capacity equal to a power of two (such as the capacity of 2 GB, 4 GB, 8 GB or 256 GB), but they can have any memory capacity (such as the capacity of 3.5 GB, 800 MB or 460 GB). In other words, the present invention maximizes the restoration of a memory unit having each normal area, obtains a memory, particularly those with a non standardized memory capacity by the reconfiguration, and provides a server or a control unit to execute an operation of reading/writing/comparing/deleting data in the same way as the conventional memory.

In summation of the description above, the present invention complies with patent application and thus is duly filed for patent application.

While the invention has been described by means of specific embodiments, numerous modifications and variations could be made thereto by those skilled in the art without departing from the scope and spirit of the invention set forth in the claims.

What is claimed is:

1. A method of restoring reconstructed memory spaces, applied for restoring usable memory spaces in an inked die to form a memory with a standardized or non-standardized memory capacity, comprising the steps of:
providing a die having at least a block, a page and a cell;
scanning at least one of the block, page and cell of the die, and writing testing data into each area corresponding to the die, so that the die produces a testing result by executing an operation of writing, reading and comparing the testing data, wherein the testing result is provided for labeling normal and abnormal blocks, pages or cells;
writing the testing result into a spare area, and displaying a density distribution of at least one of the normal and abnormal blocks, pages and cells in the die;
determining whether all of at least one of the blocks, pages and cells in the die are totally scanned and tested to repeat the aforementioned steps selectively; and
configuring and collecting the at least one block, page and cell labeled as normal to reconstruct the memory with the standardized or non-standardized memory capacity.

2. The method of restoring a reconstructed memory space as recited in claim 1, wherein the at least one of the blocks, pages and cells labeled as abnormal shows that the block, the page and the cell are a bad block, a bad page and a bad cell respectively, and cannot execute an operation of writing, reading and comparing the testing data.

3. The method of restoring a reconstructed memory space as recited in claim 2, further comprising the steps of determining whether the testing data can be written into each area, and reading the written testing data from each area to compare a difference between previous and present testing data to determine whether each area is normal or abnormal, after the step of writing the testing data into each area corresponding to the die is finished.

4. The method of restoring a reconstructed memory space as recited in claim 3, wherein the step of configuring and collecting the dies labeled as normal selects the at least one of the normal blocks, pages and cells from the spare area, and deletes the at least one of the abnormal blocks, pages and cells.

5. The method of restoring a reconstructed memory space as recited in claim 4, wherein the at least one of the selected normal blocks, pages and cells is used for reconfiguring and reconstructing the memory.

6. The method of restoring a reconstructed memory space as recited in claim 5, further comprising: providing a control unit to access the reconstructed memory, wherein the memory capacity of the memory is formed by reconfiguring the normal block.

7. The method of restoring a reconstructed memory space as recited in claim 6, wherein the memory capacity is a non-standardized memory capacity which is not equal to a power of two.

8. The method of restoring a reconstructed memory space as recited in claim 5, wherein the step of configuring and collecting at least one of the blocks, pages and cells labeled as normal adopts an embedded error correction code engine (ECC Engine) for dynamically determining whether at least one of the blocks, pages and cells is normal.

9. The method of restoring a reconstructed memory space as recited in claim 8, further comprising: configuring and collecting at least one of the blocks, pages and cells relabeled as normal to dynamically form the memory with a standardized or non-standardized memory capacity.

10. The method of restoring a reconstructed memory space as recited in claim 1, wherein the memory is an NOR flash memory, an NAND flash memory or a dynamic random access memory (DRAM).
